(19) United States
(12) Patent Application Publication
(10) Pub. No.: US 2019/0299890 A1
(43) Pub. Date: Oct. 3, 2019

(54) MCSU LIVE FIRE DETECTION APPARATUS, SYSTEM, AND METHOD

(71) Applicant: SCHROTH SAFETY PRODUCTS LLC, POMPANO BEACH, FL (US)

(72) Inventor: Neal Jenkins, Boynton Beach, FL (US)

(73) Assignee: SCHROTH SAFETY PRODUCTS LLC, POMPANO BEACH, FL (US)

(21) Appl. No.: 16/315,968

(22) PCT Filed: Jul. 7, 2017
(86) PCT No.: PCT/US17/41270

§ 371 Date: Jan. 7, 2019

Related U.S. Application Data
(60) Provisional application No. 62/359,555, filed on Jul. 7, 2016.

(51) Int. Cl. B60R 21/01; G01R 31/00

(52) U.S. Cl. CPC B60R 21/01; B60R 2021/01197; G01R 31/006

(57) ABSTRACT

A preferred embodiment of the invention is directed toward a live fire detection apparatus. The apparatus has a self-contained testing circuit, a MCSU interface, and a user-interface. This embodiment is contemplated to be used as a portable tester that a technician can use on multiple MCSUs to test for a live fire condition prior to connecting the inflator wire harness.

### CROSS-REFERENCE TO RELATED APPLICATIONS

This is a National Stage Entry of PCT/US17/41270, filed on Jul. 7, 2017, which claims the benefit of U.S. Provisional Patent Application No. 62/359,555, filed on Jul. 7, 2016.

### FIELD OF THE INVENTION

This invention relates generally to the field of electrical diagnostic equipment, devices, and systems and related methods and, more specifically to apparatus, systems, and methods for testing the live fire condition of a mechanical crash sensor unit.

### BACKGROUND

The current state of the art in vehicle passenger protection involves airbag systems that rapidly inflate under prescribed conditions. These airbag systems are typically comprised of a mechanical crash sensor unit (MCSU) and a wire harness that terminates in one or more initiators (also known as “squibs”), which fire when signaled by the MCSU and inflate the one or more airbag.

The different components of the airbag system (MCSU, harness, airbag, etc. . . . ) are capable of being independently installed, maintained, and replaced in the vehicle as needed. For example, after a firing event, it may be desirable to install and a new airbag and harness, but retain the existing MCSU.

Maintenance technicians, however, face the risk of accidental ignition of the squibs and inflation of the airbag if the MCSU is in a “fire” condition when the technician connects the harness to the MCSU. The current state of the art does not provide a way to measure if the MCSU is sending the signal to “fire”, prior to the maintenance technician hooking up the final airbag wire to the MCSU.

In addition to being a safety hazard for the maintenance technician performing the installation, it is costly in terms of time and resources to have to replace, or re-install, an accidentally inflated airbag.

It would, therefore, be desirable to have a live fire indicator, which is configured to warn of an unsafe condition of the MCSU and that is further configured to be portable and easy to use by a maintenance technician. It would also be desirable to have a live fire indicator that is configured to remain attached, in-line with the MCSU and wire harness, for simple and continuous monitoring for a live fire condition.

While certain aspects of conventional technologies and methods in the relevant art have been discussed to facilitate disclosure of the invention, Applicant in no way disclaims these technical aspects or methods, and it is contemplated that the claimed invention may encompass one or more of the conventional technical aspects or methods discussed herein.

In this specification, where a document, act, or item of knowledge is referred to or discussed, this reference or discussion is not an admission that the document, act, or item of knowledge or any combination thereof was, at the priority date, publicly available, known to the public, part of common general knowledge, or otherwise constitutes prior art under the applicable statutory provisions; or is known to be relevant to an attempt to solve any problem with which this specification is concerned.

### DESCRIPTION

In this specification and drawings, words and phrases have the meanings commonly attributed to them in the relevant art except as otherwise specified herein.

The present invention may address one or more of the problems and deficiencies of the prior art discussed above. However, it is contemplated that the invention may prove useful in addressing other problems and deficiencies in a number of technical areas. Therefore, the claimed invention should not necessarily be construed as limited to addressing any of the particular problems or deficiencies discussed herein.

In view of the foregoing, a preferred embodiment of the invention is directed toward a live fire detection apparatus. The apparatus is generally comprised of a self-contained testing circuit, a MCSU interface, and a user-interface. This embodiment is contemplated to be used as a portable tester that a maintenance technician can use on multiple MCSU's to test for a live fire condition prior to connecting the inflator wire harness.

A live fire condition occurs in the crash sensor (MCSU) when it:

detects an appropriate acceleration and triggers; or

an internal fault occurs.

The apparatus measures the voltage across the MCSU connector pins electrically connected to the firing loops and will illuminate the live fire indicator (LED) when the voltage difference is sufficient to indicate a live fire condition. The LED will continue to illuminate as long as a live fire condition exists.

Additional, non-limiting, embodiments of the present invention disclose an apparatus for detecting a live fire condition in an MCSU that is comprised of a self-contained testing circuit, a user interface, an MCSU interface, and a wire harness interface. This embodiment is contemplated to be used as an in-line tester that may remain attached to the MCSU.

The result is that, by utilizing the invention disclosed herein, a maintenance technician, or other person, may be able to safely determine if a live fire condition exists relative to a particular MCSU prior to connecting the inflator wire harness.

It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with and/or in the context of other particular aspects and embodiments of the invention, and in the invention generally.

The term “comprises” and grammatical equivalents thereof are used herein to mean that other components, ingredients, steps, etc. are optionally present. For example, an article “comprising” (or “which comprises”) components A, B, and C can consist of (i.e., contain only) components A, B, and C, or can contain not only components A, B, and C but also one or more other components.

The term “at least” followed by a number is used herein to denote the start of a range beginning with that number (which may be a range having an upper limit or no upper limit, depending on the variable being defined). For example, “at least 1” means 1 or more than 1. The term “at most” followed by a number is used herein to denote the end of a range ending with that number (which may be a range having 1 or 0 as its lower limit, or a range having no lower limit, depending upon the variable being defined). For example, “at most 4” means 4 or less than 4, and “at most 40%” means 40% or less than 40%. When, in this specification, a range is given as “(a first number) to (a second number)” or “(a first number)-(a second number),” this means a range whose lower limit is the first number and whose upper limit is the second number. For example, 25 to 100 mm means a range whose lower limit is 25 mm, and whose upper limit is 100 mm.

In this specification and in the appended claims and drawings, “vehicle”, including grammatical equivalents, singular and plural, is to be understood as a means of transport including, but not limited to, cars, trucks, vans, busses, boats, airplanes, or helicopters.

The terms “adapted” and “configured” are used interchangeably herein to state that a system or apparatus and machine can perform a certain function and is recited herein to provide guidance to those skilled in the art as to the scope of the claim.

Any element in a claim that does not explicitly state “means for” performing a specified function, or “step for” performing a specific function, is not to be interpreted as a “means” or “step” clause as specified in 35 U.S.C. § 112, ¶6. In particular, the use of “step of” in the claims herein is not intended to invoke the provisions of 35 U.S.C. § 112, ¶6.

While the specification will conclude with claims defining the features of embodiments of the invention that are regarded as novel, it is believed that the invention will be better understood from a consideration of the following description in conjunction with the figures, in which like reference numerals are carried forward.

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein. Specifically, component names, types, and values, as depicted in the exemplary schematic diagrams, are not intended to limit the scope of the present invention and are presented only as possible embodiments.

The various embodiments of the invention disclosed and described herein are contemplated to be applicable to other types of vehicles as well, regardless of whether for air, land, sea, or space travel.

APPARATUS 100: Stand-alone MCSU Live Fire Condition Tester

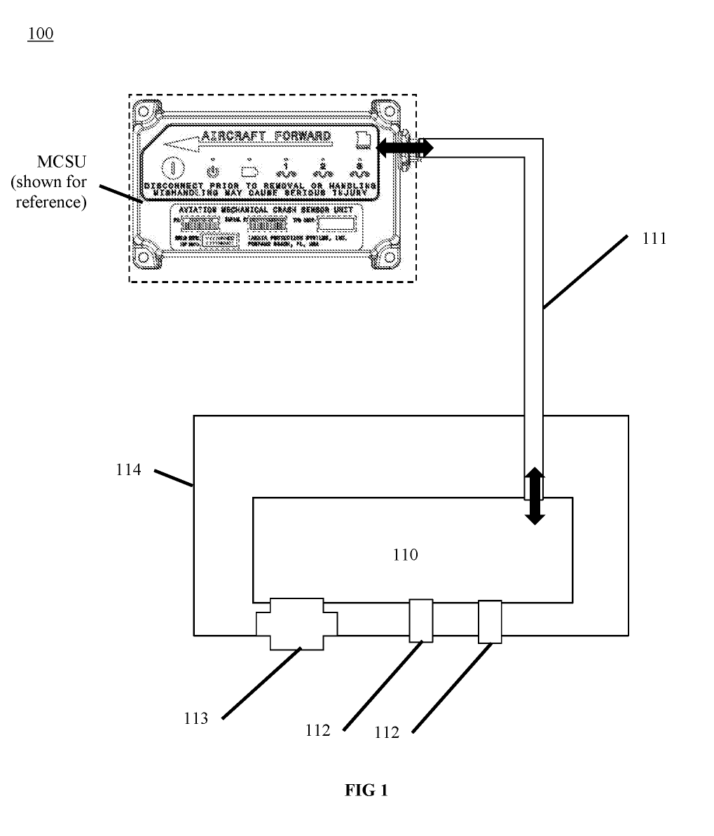

Referring to the figures in general, and to FIG. 1 in particular, we discuss now a preferred embodiment of the present invention in the form of stand-alone MCSU live fire condition tester apparatus 100 comprising: a detection circuit 110; an input 111 electrically connected to the detection circuit 110 and configured to receive a one or more electrical signal from an MCSU; a one or more visual indicator 112 electrically connected to the detection circuit 110; and a test button 113 electrically connected to the detection circuit 110.

The apparatus 100 may further comprise a housing 114.

The detection circuit 110 is an electrical circuit configured to monitor input 111, which is the voltage across the MCSU firing loops, and will activate the one or more visual indicator 112, for example, an LED, when the voltage difference is sufficient to indicate a live fire condition.

The apparatus 100 can be configured to test one or multiple firing loops (MCSU's are known to be configured to trigger one or multiple initiators) by configuring the input 111 accordingly.

The detection circuit 110 may be made using discrete components, using an integrated circuit, a programmable microcontroller, or a combination thereof.

The input 111 may be made from a wire harness, or cable, with multiple internal conductors. On one end, the conductors are configured to electrically interface with the detection circuit 110 and the other end of the conductors are configured to interface with the MCSU.

The visual indicator 112 may be a one or more light emitting diode (LED), an LCD panel, or other means capable of electrically communicating with the detection circuit 110 and outputting a visual signal. By way of example, and not limitation, the visual indicator may be a red LED and a green LED, both electrically connected to the detection circuit 110.

The test button 113 is a momentary switch as is known in the art that is capable of opening or closing a circuit by virtue of pressing or releasing a button. The test button 113 is configured to be electrically connected to the detection circuit 110.

In operation, an embodiment of the apparatus 100 may be used to detect if an MCSU is in a live fire condition by the following method:

providing an MCSU test apparatus 100, as described herein;

providing an MCSU for testing;

connecting the apparatus 100 input 111 to the MCSU output (wire harness connector);

sensing by the detection circuit 110 if a voltage is present across firing loops;

comparing by the detection circuit 110 the voltage difference across firing loops; and

illuminating of the red LED by the detection circuit, if the voltage difference is greater than a predetermined value.

Additionally, a non-live fire condition may be confirmed by pressing the test button and observing if the green LED illuminates.

In the event that the red LED is off, and the green LED does not illuminate when pressing the test button, the MCSU should be considered in a live fire condition and should be removed from service.

When a non-live fire (safe) condition is confirmed by using the apparatus 100, then the apparatus 100 may be disconnected from the MCSU and the initiator wire harness may be safely connected without fear of unintentionally triggering the airbag inflators.

Apparatus 200: In-Line MCSU Live Fire Condition Tester

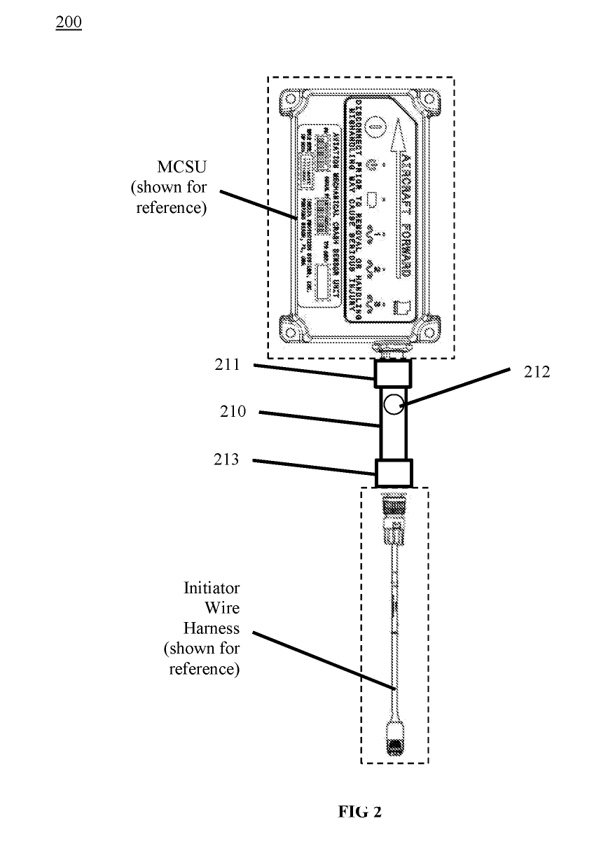

Another embodiment of the present invention contemplates an in-line version of the invention that is configured to remain attached to the MCSU. Such an embodiment, illustrated in FIG. 2 and disclosed as apparatus 200, comprises: a detection circuit 210; an input 211 electrically connected to the detection circuit 210 and configured to receive a one or more electrical signal from an MCSU; a one or more visual indicator 212 electrically connected to the detection circuit 210; and an output 213 electrically connected to the detection circuit 210 and configured to pass the electrical signals received from the MCSU through the input 211 to an attached initiator wire harness.

By way of example, and not limitation, FIG. 2 illustrates an embodiment of the present invention in the form of apparatus 200 installed in-line with the MCSU at the input 211 and the wire harness at the output 213.

An LED (visual indicator 212) would illuminate if a live fire condition exists, in conformity with Boeing D6-3440 requirement 5.6.8.c.

During diagnostics, an LED would illuminate proving functionality, in conformity with Boeing D6-3440 requirement 5.6.8.d.

For embodiments of the present invention adapted for use in vehicles regulated by the Federal Aviation Administration (FAA), the materials, structures, and manufacturing methods used are contemplated to comply with applicable Federal Aviation Requirements (FARs).

It will be appreciated that the devices, apparatus, and systems described above are set forth by way of example and not of limitation. Numerous variations, additions, omissions, and other modifications will be apparent to one of ordinary skill in the art.

While particular embodiments of the present invention have been shown and described, it will be apparent to those skilled in the art that various changes and modifications in form and details may be made therein without departing from the spirit and scope of the invention.

In light of the foregoing description, it should be recognized that embodiments in accordance with the present invention can be realized in numerous configurations contemplated to be within the scope and spirit of the claims. Additionally, the description above is intended by way of example only and is not intended to limit the present invention in any way.

1. An apparatus for testing for a live fire condition in a mechanical crash sensing unit, the apparatus comprising:
a detection circuit;
an input electrically connected to the detection circuit, said input configured to receive a one or more electrical signal from an MCSU;
a one or more visual indicator electrically connected to the detection circuit; and
a test button electrically connected to the detection circuit.

2. The apparatus of claim 1, further comprising a housing.

3. A method of utilizing the apparatus of claim 1 to detect if an MCSU is in a live fire condition, the steps of the method comprising:
providing the apparatus of claim 1;
providing an MCSU for testing;
connecting the apparatus input to the MCSU output;
sensing the by the detection circuit the voltage difference across firing loops; and
illuminating of a red LED by the detection circuit, if the voltage difference is greater than a predetermined value or illuminating of a green LED by the detection circuit if the voltage difference is less than a predetermined value.
